(19) United States
(12) Patent Application Publication
(10) Pub. No.: US 2011/0292610 A1
(43) Pub. Date: Dec. 1, 2011

(54) HEAT SINK AND ELECTRONIC APPARATUS USING THE SAME

(75) Inventor: ZEU-CHIA TAN, Tu-Cheng (TW)

(73) Assignee: HON HAI PRECISION INDUSTRY CO., LTD., Tu-Cheng (TW)

(21) Appl. No.: 12/832,946

(22) Filed: Jul. 8, 2010

(30) Foreign Application Priority Data
Jun. 1, 2010 (TW) 99117582

(51) Int. Cl. H05K 7/20; F28F 7/00

(52) U.S. Cl. 361/710; 165/185

(57) ABSTRACT

A heat sink includes a bottom plate, a plurality of fins, an extending member, and a heat conduction member. The plurality of fins is fixed on the bottom plate. The extending member extends outward from an end of the bottom plate. The heat conduction member depends from an end of the extending member.

### BACKGROUND

1. Technical Field

The present disclosure relates to heat sinks and, particularly, to a heat sink fixed to an electronic apparatus.

2. Description of Related Art

It is well known that many electronic systems comprising many electronic components generate a large amount of heat, and that the heat must be promptly removed from the electronic components to ensure proper operation. Generally, such components need heat sinks mounted thereon to remove the heat generated thereby. As a result, some modern heat sinks are small, and correspondingly have small heat dissipation capability. Thus, the heat generated by the electronic components may not be removed rapidly enough. Furthermore, many systems may not have effective heat removal means for their electronic components.

Therefore, a heat sink is desired to overcome the limitations described.

### BRIEF DESCRIPTION OF THE DRAWINGS

Many aspects of the present device can be better understood with reference to the following drawings. The components in the drawings are not necessarily drawn to scale, the emphasis instead being placed upon clearly illustrating the principles of the present heat sink. Moreover, in the drawings, like reference numerals designate corresponding parts throughout the several views.

FIG. 1 is an isometric view of a heat sink according to an exemplary embodiment.

FIG. 2 is an isometric view of a circuit board and an isometric view of the heat sink of FIG. 1.

FIG. 3 is an assembled, sectional view of a chassis, the circuit board, and the heat sink.

### DETAILED DESCRIPTION

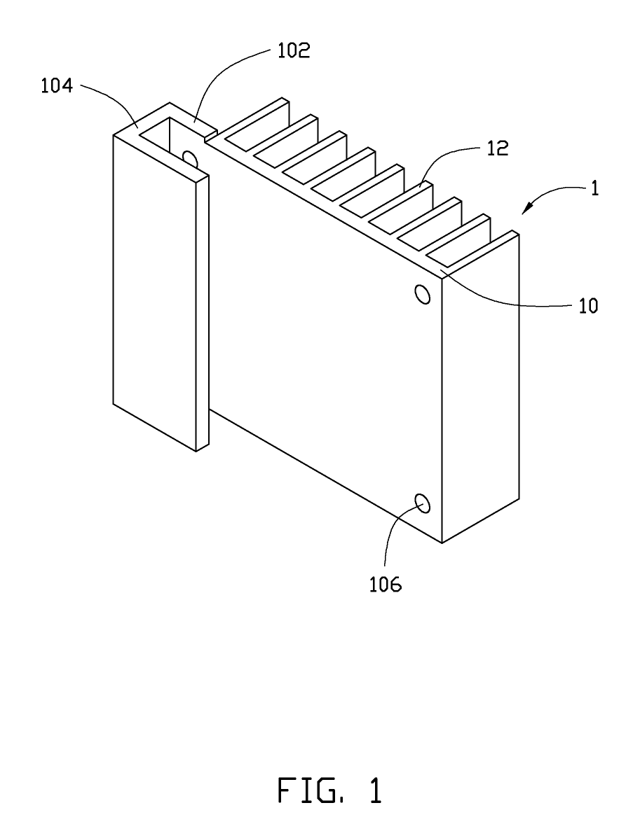

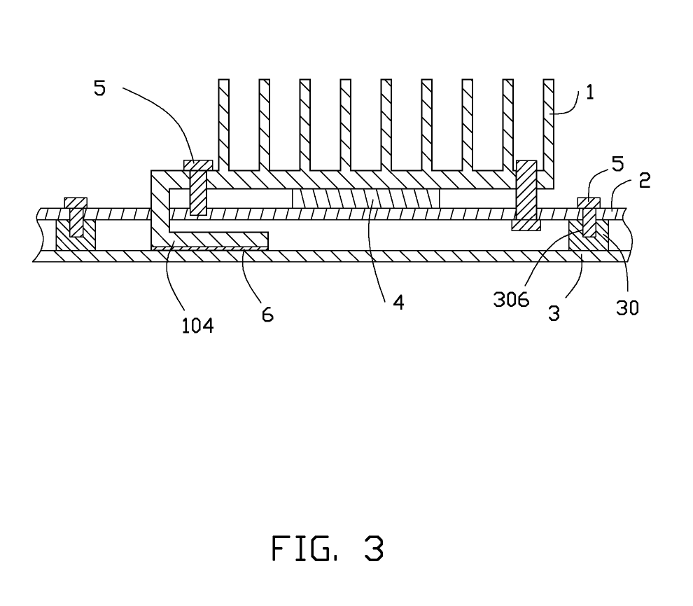

Referring to FIGS. 1 and 3, an electronic apparatus, according to an exemplary embodiment, is shown. The electronic device includes a chassis 3, a circuit board 2 installed in the chassis 3, and a heat sink 1 fixed to the circuit board 2 for cooling an electronic element 4 mounted to the circuit board 2.

The heat sink 1 includes a bottom plate 10 and a plurality of fins 12 formed on the bottom plate 10. An extending member 102 extends outward from an end of the bottom plate 10. A heat conduction member 104 depends from an end of the extending member 102. In the illustrated embodiment, the heat conduction member 104 is L-shaped. A plurality of first threaded holes 106 is defined in the extending member 102 and the bottom plate 10.

The chassis 3 is made of metal. A plurality of fixed members 30 is punched outward from the chassis 3. A third threaded hole 306 is defined in each top portion of the fixed member 30.

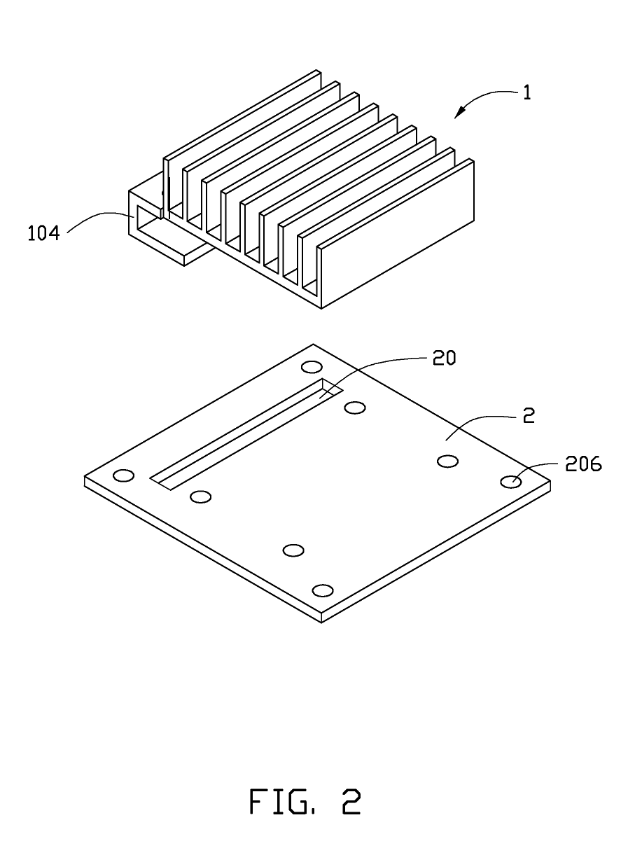

Referring to FIG. 2, the circuit board 2 defines a slot 20 and a plurality of second threaded holes 206. The slot 20 is positioned corresponding to the heat conduction member 104 of the heat sink 1. The plurality of second threaded holes 206 is positioned corresponding to the third threaded hole 306 of the chassis 3.

Referring to FIG. 3, the circuit board 2 and the chassis 3 can be secured to each other by fastening means 5 each running through one second threaded hole 206 of the circuit board 2 and one third threaded hole 306 of the fixed member 30. The heat conduction member 104 angles through the slot 20 of the circuit board 2 to contact the chassis 3. A thermal pad 6 is disposed between the heat conduction member 104 and the chassis 3. Thus the heat conduction member 104 is in tight contact with the chassis 3 for evacuating heat from the electronic element 4 to the chassis 3. The heat sink 1 and the circuit board 2 can be secured to each other by fastening means 5 each running through one first threaded hole 106 of the heat sink 1 and one second threaded hole 206 of the circuit board 2.

In use, heat can be evacuated by the plurality of fins 12 and the heat conduction member 104, such that heat dissipation area of the heat sink 1 is increased, and heat dissipation efficiency is improved.

While the invention has been described by way of example and in terms of preferred embodiment, it is to be understood that the invention is not limited thereto. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A heat sink, comprising:
a bottom plate;
a plurality of fins fixed on the bottom plate;
an extending member extending outward from an end of the bottom plate; and
a heat conduction member depending from an end of the extending member.

2. The heat sink of claim 1, wherein the heat conduction member is L-shaped.

3. The heat sink of claim 1, wherein the bottom plate and the extending member define a plurality of first threaded holes.

4. An electronic apparatus, comprising:
a chassis;
a circuit board fixed on the chassis, wherein the circuit board comprises an electronic element fixed on the circuit board and a slot defined in the circuit board; and
a heat sink fixed on the circuit board for cooling the electronic element, wherein the heat sink comprises:
a bottom plate;
a plurality of fins fixed on the bottom plate;
an extending member extending outward from an end of the bottom plate; and
a heat conduction member depending from an end of the extending member to angle through the slot of the circuit board to thermally contact the chassis.

5. The electronic apparatus of claim 4, wherein the heat conduction member is L-shaped.

6. The electronic apparatus of claim 4, wherein the bottom plate and the extending member define a plurality of first threaded holes.

7. The electronic apparatus of claim 4, wherein the chassis comprises a plurality of fixed members punched outward from the chassis, and wherein each of the fixed members comprises a third threaded hole defined in a top portion of the fixed member.

8. The electronic apparatus of claim 7, wherein the circuit board comprises a plurality of second threaded holes, wherein each of the second threaded holes is positioned corresponding to one of the third threaded holes for securing the circuit board to the chassis by fastening means.

9. The electronic apparatus of claim 4, further comprising a thermal pad, wherein the thermal pad is disposed between the heat conduction member and the chassis.
